(19) United States
(12) Patent Application Publication
(10) Pub. No.: US 2012/0196444 A1
(43) Pub. Date: Aug. 2, 2012

(54) METHOD FOR THE SELECTIVE DELIVERY OF MATERIAL TO A SUBSTRATE

(75) Inventors: Alison Joan Lennon, Rozelle New South Wales (AU); Stuart Ross Wenham, Cronulla (AU)

(73) Assignee: New South Innovations PTY Limited, NSW (AU)

(21) Appl. No.: 13/389,735

(22) PCT Filed: Aug. 6, 2010
(86) PCT No.: PCT/AU10/01001

§ 371 Date: Apr. 18, 2012

(30) Foreign Application Priority Data
Aug. 11, 2009 (AU) 2009903752

(51) Int. Cl. H01L 21/311

(52) U.S. Cl. 438/703; 257/E21.249

(57) ABSTRACT

A method of selective delivery of material to locations on a substrate using a continuous stream deposition device to deposit the material at selected locations on the substrate. This is achieved by creating a mask with an opening, locating the mask over the substrate and depositing the material through the opening onto the substrate. When locating the mask, over the substrate, a portion of the substrate is exposed through the opening and when the continuous stream deposition device is moved relative to the substrate and the mask, the continuous stream deposition device follows a path relative to the mask which intersects the opening. While the continuous stream deposition device moves, it discharges a continuous stream comprising the material to be delivered, to deposit the material through the mask at a discrete location on the substrate, at the intersection of the opening and the path of the continuous stream deposition device. Alternatively the mask may be dispensed with and two materials deposited on two intersecting paths whereby at the intersections the two materials react.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### TECHNICAL FIELD OF THE INVENTION

The present invention relates generally to the field of device fabrication and, in particular, to the selective delivery of material to discrete locations on a substrate.

The techniques, developed for use in solar cell fabrication, are also applicable to other areas where selective procession of a surface is required. The techniques are applicable to deposition processes as well as etching.

### BACKGROUND OF THE INVENTION

Semiconductor device fabrication typically involves extensive use of patterned etching of both semiconductor and dielectric materials. In particular, the formation of patterns of openings in silicon dioxide dielectric layers of silicon devices is widely used because of the passivating and optical effects of silicon dioxide on silicon surfaces. Patterned etching of silicon dioxide layers can be used to facilitate localised diffusions and metal contacts to underlying silicon, or in other cases, to provide a mask for etching the underlying silicon. In the case of solar cells, the patterning of groove and hole openings in dielectric layers is routinely used to form metal contacts to the cells. Arrays of hole openings are often used in preference to groove openings in order to reduce the recombination of carriers at the semiconductor-metal interface.

Typically, the etching of hole openings in dielectric layers, such as silicon dioxide and silicon nitride, has been achieved using photolithography. However, photolithography requires costly equipment (e.g., mask aligners, mask writers), clean room environments, and generally many time-consuming steps. Changes in patterns require new mask sets. A typical photolithographic process for the formation of a pattern of openings in a dielectric typically requires deposition of a resist layer over the dielectric layer (usually by spin-coating), appropriately aligning a prepared mask over the resist layer, exposing the resist through the mask to UV radiation and then developing the exposed resist to form a pattern of openings in the resist. The resist with a pattern of openings is then used as a mask against etchants in wet etching and physical etching (e.g. ion etching) applications. Etching fluids for silicon dioxide typically comprise aqueous hydrogen fluoride or a buffered oxide etching solution, both of which are highly corrosive. The device is then rinsed to remove traces of the etchant, and finally the resist layer is removed to leave a patterned dielectric layer on the device.

More recently, drop-on-demand inkjet methods of patterning dielectric layers have been described. Most of these methods involve using an inkjet to pattern a resist layer and so resemble the complexity of photolithography and require the use of large quantities of chemicals, in particular resins for resist and corrosive etching solutions. Furthermore, in order to achieve small etched hole sizes using drop-on-demand inkjet printing approaches, typically small droplet volumes (e.g., 1 pL) are required to avoid spreading of the deposited solution on the substrate. The droplet volume places a lower limit on the size of etched holes. So, for example, drop-on-demand inkjet patterning processes employing droplet volumes of 1 pL typically result in etched hole diameters of 40-50 μm. The use of these small drop volumes typically requires the deposition of many layers in order to pattern a resist layer or directly etch material, such as a dielectric layer, thus making the process inherently slow and therefore unsuitable for commercial production.

For this reason, continuous stream based delivery of fluids, which are capable of effecting etching of a substrate of selected material, is desirable. These continuous stream deposition techniques, which include continuous inkjet, electrohydrodynamic printing and aerosol jet printing, are generally limited by stage processing speeds and, to a lesser extent, material or fluid flow rates. However, although these methods are well-suited to line-based patterning of substrates, it is difficult to achieve etched patterns comprising arrays of openings, such as circular holes, which require the deposition of small amounts of active material at discrete, or point-like, locations on the substrate. Approaches, such as shuttering, are often used to temporarily halt the delivery of the stream of fluid to the surface. However, the act of shuttering can affect the stability of the continuous flow resulting in inconsistent deposition patterns. Furthermore, the shuttering action is often mechanical resulting in limited actuation speeds and mechanical wear and tear over long periods of operation. Finally, material can build up on the shutter, resulting in overflow of built-up fluid onto the substrate.

Therefore, advances which can enable fast and effective delivery of materials, such as fluids which can result in etching, to discrete locations on the substrate are desirable. In order to be commercially viable, robust methods which do not result in high levels of mechanical wear and tear or require extensive maintenance are desirable.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect of the invention, there is provided a method of selective delivery of material to locations on a substrate using a continuous stream deposition device, the method comprising the steps of:

locating a mask over the substrate, the mask having an opening through which a portion of the substrate is exposed;

moving the continuous stream deposition device and/or the substrate and the mask such that the continuous stream deposition device follows a path relative to the mask while discharging a continuous stream comprising the material such that the continuous stream moves over the opening to deposit the material at a discrete location on the substrate, and such that a pattern of the material deposited on the substrate is different to a pattern of the opening in the mask.

The opening in the mask may be a substantially linear opening. A plurality of substantially linear opening may be provided in the mask and the linear openings may be parallel with respect to each other. The path of the continuous stream deposition device may cross each opening at a predetermined angle. The predetermined angle may be generally (or substantially) ninety degrees.

The method may further comprise the step of rotating the mask to change the angle and vary a distance between the openings along the path of the continuous stream deposition device.

In one embodiment, a surface of the mask is planar. In another embodiment, a surface of the mask includes a valley having a lowest point at a location corresponding to the opening. In another embodiment, a surface of the mask includes a ridge having a peak at a location corresponding to the opening. The ridge may direct material discharged onto the mask to a reservoir for collection. The mask may also comprise a plurality of mask elements superimposed on one another, each mask element having openings of the same periodicity as the other mask elements and each mask element being offset relative to the other mask elements to form effective openings smaller than the openings in each mask element.

The mask may be maintained at a predetermined distance above the substrate.

The mask may be printed on the substrate using one of a printing device, a screen printer, a continuous flow inkjet printer, a drop-on-demand inkjet printer, an electrohydrodynamic printer, and an aerosol jet printer.

The material deposited on the substrate through the opening may modify the substrate in an additive manner.

The continuous stream device may be one of a continuous flow inkjet device, an electrohydrodynamic printing device, and an aerosol jet printing device.

The continuous stream may be an aerosol stream.

The method may further include a step of controlling a flow rate of the aerosol stream. The method may further include constraining the aerosol stream with a sheath gas.

The material may include a first reactive component which is reactive with a second reactive component on contacting the substrate. The substrate may comprise the second reactive component.

The method may include the step of depositing the second reactive component on the substrate prior to the step of locating the mask.

The material may include the first reactive component and the second reactive component and the first reactive component and the second reactive component may be delivered to the surface of the substrate without substantial interaction prior to contacting the surface of the substrate.

The first reactive component and the second reactive component may be delivered to the surface of the substrate within the same continuous stream. The continuous stream deposition device may include a first nozzle to discharge the first reactive component and a second nozzle to discharge the second reactive component.

The first reactive component and the second reactive component may react with each other at the surface of the substrate to become reactive with respect to a component of the substrate to modify the substrate at the location.

The first reactive component may comprise one of a source of fluoride ions and acidic polymer and the second reactive component may comprise the other of the source of fluoride ions and the acidic polymer. The source of fluoride ions may be one or more of ammonium fluoride, a tetra alkyl ammonium fluoride, sodium fluoride, and lithium fluoride.

The second reactive component may be a surface polymer layer. The surface polymer layer may be acidic. The surface polymer layer may be water-soluble.

The material deposited on the substrate may react with the substrate to modify the substrate at the location. The substrate may be modified by etching of a component of the substrate.

The component of the substrate which is etched may be one of a compound selected from silicon dioxide, silicon nitride and silicon carbide; a transparent conducting oxide; a glass; an organic resin; a pattern mask material; a metal selected from aluminium, copper, silver, gold, tin, lead and alloys thereof; a semiconductor material selected from silicon, germanium, gallium-arsenide and indium phosphide; and a semiconductor alloy selected from silicon-germanium, aluminium-gallium-arsenid, indium-selenide, galium-selenide, cadmium-telluride and copper indium gallium selenide (CIGS).

The substrate may be a silicon solar cell device precursor having a dielectric layer and the etching results in an array of openings in the dielectric layer. The openings may be used to form metal contacts to the silicon solar cell device.

The method may comprise the steps of: depositing a first reactive component on the substrate according to a first deposition path; and depositing a second component on the substrate according to a second deposition path, the second deposition path intersecting the first deposition path at the discrete location.

The method may comprise the step of modifying the substrate only at the discrete location by the action of the first reactive component and the second reactive component together.

The material may comprise a first reactive component and a second reactive component and the step of moving the continuous steam device may comprise:

discharging a first continuous stream including the first reactive component over the mask in a deposition path to apply the first reactive component through the opening to the location; and

discharging a second continuous stream including the second reactive component over the mask in the deposition path to apply the second reactive component through the opening to the deposited first reactive component.

According to a second aspect of the invention, there is a method of processing a surface at a discrete location on a substrate using a continuous stream deposition device, the method comprising:

depositing a first reactive component according to a first deposition path;

depositing a second reactive component according to a second deposition path, the second deposition path intersecting the first deposition path at the discrete location; and

modifying the substrate only at the discrete location by the action of the first reactive component and the second reactive component together.

The second deposition path may intersect the first deposition path at a predetermined angle. The predetermined angle may be approximately ninety degrees.

The continuous stream deposition device may be one of a continuous flow inkjet device, an electrohydrodynamic printing device, and an aerosol jet printing device. The continuous stream may be an aerosol stream.

The method may include controlling a flow rate of the aerosol stream. The method may include constraining the aerosol stream with a sheath gas.

The surface may be additively modified.

The first reactive component may be reactive with the second reactive component. The first reactive component and the second reactive component may react with each other at the surface of the substrate to become reactive with respect to a component of the substrate to modify the substrate at the discrete location.

The first reactive component may contain one of a source of fluoride ions and acidic polymer and the second reactive component may contain the other of the source of fluoride ions and the acidic polymer.

The source of fluoride ions may be one or more of: ammonium fluoride, a tetra alkyl ammonium fluoride, sodium fluoride, and lithium fluoride.

The acidic polymer may be water-soluble.

The substrate may be modified by etching of a component of the substrate. The component of the substrate which is etched may be one of a compound selected from silicon dioxide, silicon nitride and silicon carbide; a transparent conducting oxide; a glass; an organic resin; a pattern mask material; a metal selected from aluminium, copper, silver, gold, tin, lead and alloys thereof; a semiconductor material selected from silicon, germanium, gallium-arsenide and indium phosphide; and a semiconductor alloy selected from silicon-germanium, aluminium-gallium-arsenid, indium-selenide, galium-selenide, cadmium-telluride and copper indium gallium selenide (CIGS).

The substrate may be a silicon solar cell device precursor having a dielectric layer and the etching may result in an array of openings in the dielectric layer. The openings may be used to form metal contacts to the silicon solar cell device.

According to a third aspect of the invention, there is provided a method of depositing material including a first reactive component and a second reactive component at a discrete location on a substrate using a continuous stream deposition device, the method comprising the steps of

locating a mask over a substrate, the mask having an opening through which a portion of the substrate is exposed;

moving a first continuous stream including the first reactive component over the mask in a deposition path to apply the first reactive component through the opening to the discrete location; and

moving a second continuous stream including the second reactive component over the mask in the deposition path to apply the second reactive component through the opening to the deposited first reactive component.

According to a fourth aspect of the invention, there is provided a mask for use in depositing material in a pattern on a substrate using a continuous stream deposition device, the mask comprising:

an operatively upper surface;

an operatively lower surface; and

an opening formed through the mask from the operatively upper surface to the operatively lower surface and through which the material to be deposited on the substrate passes;

the operatively upper surface being contoured to direct a flow of the material deposited on the mask across the mask.

The contouring of the upper surface may comprise a valley having a lowest point corresponding to the opening such that the flow of the material is directed toward the opening for deposition on the substrate through the opening. The opening and the valley may be generally linear.

The contouring of the upper surface may comprise a ridge having a peak corresponding to the opening such that the flow of the material is directed away from the opening. The ridge and the opening may be substantially linear.

The mask may further comprise a reservoir; and a channel for draining the material directed away from the opening to a reservoir for collection.

According to fifth aspect of the invention, there is provided a system to deposit material in locations on a substrate comprising:

a mask for location over the substrate, the mask having an opening through which a portion of the substrate is exposable;

a continuous stream deposition device to discharge a continuous stream comprising the material; and

a transport system to move the continuous stream deposition device and/or the substrate and the mask such that the continuous stream deposition device follows a path relative to the mask while discharging the continuous stream such that the continuous stream moves over the opening to deposit the material at a discrete location on the substrate, and such that a pattern of the material deposited on the substrate is different to a pattern of the opening in the mask.

In this system, the mask may also comprise a plurality of mask elements superimposed on one another, each mask element having openings of the same periodicity as the other mask elements and each mask element being offset relative to the other mask elements to form effective openings smaller than the openings in each mask element.

According to another aspect of the invention, there is provided a modified substrate obtained according to any one of the above methods.

According to another aspect of the invention, there is provided a silicon solar cell device obtained using the method of any one of the above methods.

There are disclosed methods of selectively delivering material to locations on a substrate with which it is possible to control the size of a deposit on the substrate by using an opening in a mask or a width of a continuous stream to limit one dimension of the deposit and using a width of a continuous stream to limit another dimension of the deposit.

### BRIEF DESCRIPTION OF THE DRAWINGS

Embodiments of the invention will now be described, by way of example, with reference to the accompanying drawings in which:

FIG. 1A is a schematic diagram showing a deposition mask of an embodiment positioned over a substrate which is supported on a platen;

FIG. 1B is a schematic diagram showing the layers of the silicon-wafer-based substrate used by the embodiment of FIG. 1A;

FIG. 1C is a schematic diagram showing a cross-section of the embodiment of FIG. 1A;

FIG. 1D is a schematic diagram showing an example of a path followed by a continuous stream deposition device relative to the substrate and the deposition mask due to movement of the continuous stream deposition device and/or the substrate and deposition mask;

FIG. 1E is a schematic diagram of an array of hole openings etched in the silicon dioxide layer of the substrate, depicted in FIG. 1B, using the embodiment depicted in FIG. 1A and FIG. 1C;

FIG. 2 is a schematic diagram showing a rotated deposition mask positioned over a substrate which is supported on a platen;

FIG. 3A is a schematic diagram showing a cross-section of an arrangement which includes a deposition mask in which sloped surfaces are used to direct material deposited on the mask to the opening;

FIG. 3B is a schematic diagram showing a cross-section of an arrangement which includes two deposition masks with openings on a common pitch such that when the openings are slightly offset the effective opening size is reduced:

FIG. 4 is a schematic diagram showing a cross-section of an arrangement which includes a deposition mask in which sloped surfaces are used to direct material deposited on the mask away from the opening and into channels;

FIG. 5A is a schematic diagram showing a cross-section of an arrangement including a printed deposition mask;

FIG. 5B is a schematic diagram showing a cross-section of an arrangement including a printed deposition mask where two sets of nozzles are used by the continuous stream deposition device;

FIG. 6 is a schematic diagram showing two deposition paths according to one embodiment;

FIG. 7A is a schematic diagram showing a cross-section of a deposition mask which is used to deposit small pillars of solid material on the substrate;

FIG. 7B is a diagram of a substrate patterned using the deposition arrangement depicted in FIG. 7A;

FIG. 8A is an image of an array of four etched holes, being part of a larger array of holes etched using the preferred arrangement;

FIG. 8B is a higher magnification image of one of the etched holes in FIG. 8A showing the profiled edges of the hole that can result in smaller contact areas for metallisation; and

FIG. 9 is a graphic which shows how series resistance losses of point contacts for silicon solar cells can be minimised by having very small opening areas spaced closely together.

### DETAILED DESCRIPTION OF EMBODIMENTS

A method and apparatus will be described which enable delivery of small amounts of material to discrete locations on a substrate using a continuous stream deposition or jetting device, such as a continuous inkjet printing device, an electrohydrodynamic printing device or an aerosol jetting device. The material may be delivered to a regular array of discrete locations, however, other deposition patterns which involve deposition of the material to non-array locations are also possible. The material delivered to the substrate is typically a liquid or an aerosol of small particles formed from a liquid and the deposition can result in additive or subtractive modification of the substrate. Subtractive modification of the substrate can be used to etch arrays of consistently-sized holes in the substrate, which can, for example, be used to form metal contacts through dielectric layers of silicon solar cells. Additive modification of the substrate can result in the formation of small structures, or pillars, on the substrate that can be used for photonic and light capturing applications.

The delivery of a material to an array of discrete locations on a substrate is not straightforward for continuous stream deposition devices. These devices typically have to employ shuttering mechanisms to temporarily halt the delivery of the stream to the surface in order to deposit discrete dots of material at the point locations. The act of shuttering can affect the stability of the continuous flow resulting in inconsistent deposition patterns. Furthermore, the shuttering action is often mechanical resulting in limited actuation speeds and mechanical wear and tear over long periods of operation. Finally, material can build up on the shutter, resulting in overflow of built-up fluid onto the substrate. For continuous flow devices it is preferable to not disturb the flow of the material (fluid or aerosol) as this typically results in a less stable flow.

Preferred arrangements of the present invention provide a method and apparatus for delivering a material to an array of discrete locations on a substrate in a point-wise manner, using a continuous stream device. The thus-deposited material may result in the etching of an array of holes in the substrate (i.e., subtractive modification of the substrate) but may also be used to add material to the surface of the substrate. In one particularly useful embodiment, the substrate is a silicon dioxide dielectric layer formed on the rear surface of a silicon solar cell, and the etched array of holes enables metal contacts to be formed to the silicon of the solar cell. However, it should be clear to those skilled in the art that the described method can also be used to etch or build patterns in other materials including, but not limited to, silicon nitride, silicon carbide, transparent conducting oxides, organic resins and other polymers including pattern mask materials, metals such as aluminium, copper, silver, gold, tin and lead or alloys thereof and semiconductor materials including silicon, germanium, gallium-arsenide, indium phosphide, or alloys such as silicon-germanium or aluminium-gallium-arsenide, indium-selenide, galium-selenide, cadmium-telluride or copper indium gallium selenide (CIGS).

A preferred method of etching an array of holes in the silicon dioxide involves the deposition a fluid containing fluoride ions, according to an etching pattern, onto an acidic water-soluble polymer layer formed over the dielectric layer. The deposited fluid reacts with the polymer layer, at the locations where it is deposited, to form an etchant that etches the silicon dioxide and silicon nitride under the polymer layer to form a pattern of openings in the dielectric layer. After the pattern of openings is formed, the acidic water-soluble polymer and the etch residue are easily removed by rinsing in water.

This etching method is disclosed in PCT patent application No. PCT/AU2009/000098, filed 29 Jan. 2009; the entirety of which is incorporated herein by reference. The method does not require a masking or resist layer and is safer than existing etching methods in that the corrosive etchant is only formed in-situ on the device surface to be etched. Furthermore, because the etchant is formed only at the locations to be etched, the method requires small amounts of chemicals and produces significantly less hazardous chemical waste. The method does not require any resist chemicals and only uses small quantities of etching precursor materials. The hazardous hydrogen fluoride waste of existing silicon dioxide wet etching methods is a concern for manufacturing processes around the world. Although the method is described here with respect to the patterned etching of silicon dioxide, it should be clear to those skilled in the art of semiconductor device fabrication that the disclosed method can be applied to the etching of other materials including metals, other dielectrics and semiconductors.

Clearly, other etching methods can also be used with the method and apparatus disclosed herein to pattern a silicon dioxide layer, or other component, of a substrate.

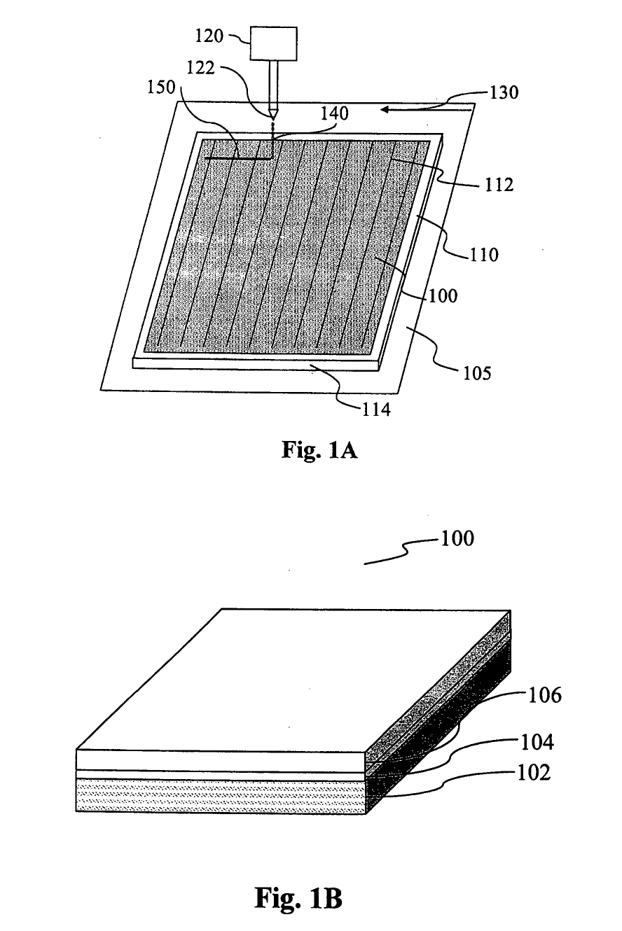

An example of a particularly useful etching process will now be described in detail with reference to the accompanying drawings. FIG. 1A shows a substrate 100 supported by a stage platen 105 of a continuous stream deposition device 120. Preferably, the substrate 100 is a silicon wafer 102 on which a silicon dioxide layer 104 has been thermally grown (FIG. 1B). The wafer 102 can be a p-type or n-type silicon wafer. The surface can be diffused with dopants of opposite polarity such as phosphorus or boron or aluminium to create an emitter. The thickness of the wafer 102 can range from 150-450 μm. Preferably, the thickness of the silicon dioxide layer 104 is in a range from about 100 to 300 nm and might typically be 200 nm, although other oxide thicknesses, for example, less than 100 nm, can also be used for other applications.

A layer of polyacrylic acid 106 (an acidic polymer layer) having a thickness preferably within a range of about 1.5 to 3 μm, and which might typically be 2.2 μm thick, is formed over the silicon dioxide layer 104. With regard to thickness, if the layer of polyacrylic acid 106 is too thin, there may be insufficient acid present for etching. Where the layer of polyacrylic acid 106 is too thick, etching of the dielectric layer is less optimal, possibly due to the fluoride ion (discussed in more detail below) concentration becoming to dilute in the dissolved polymer. This acidic polymer layer 106 is preferably formed by spin-coating a 25% (w/v) solution of polyacrylic acid at 7000 rpm for 30 seconds and then air-drying for at least two hours. The thickness of the dried polymer layer 106 can be varied by changing the weight polymer percentage of the solution used to form the coating. This acidic polymer layer 106 provides a source of protons for the etching reaction and also serves to restrict the spreading of the deposited fluid. Other acidic, water soluble polymers can also be used (e.g., acidic polythiophene or polyaniline derivatives, polystyrene sulfonate, polyester or phenolic resins). The acidic polymer layer 106 can also be formed using other methods such as spray coating or dip coating. Alternatively, it can be deposited on the surface to be etched by a continuous or drop-on-demand deposition method. This alternative arrangement is advantageous when only small regions of the substrate need to be processed because only the regions that need to be processed can be coated with the polymer, thus reducing material costs.

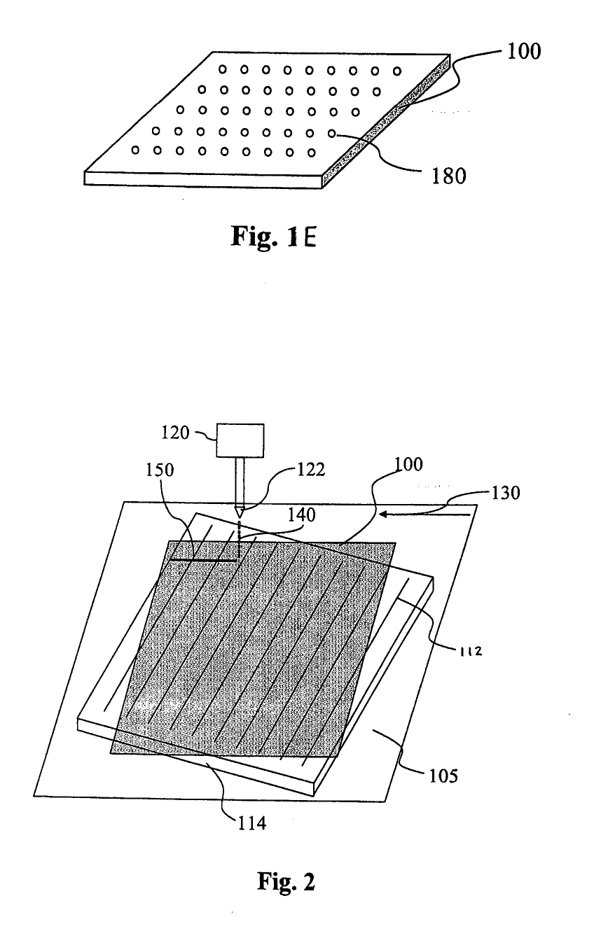

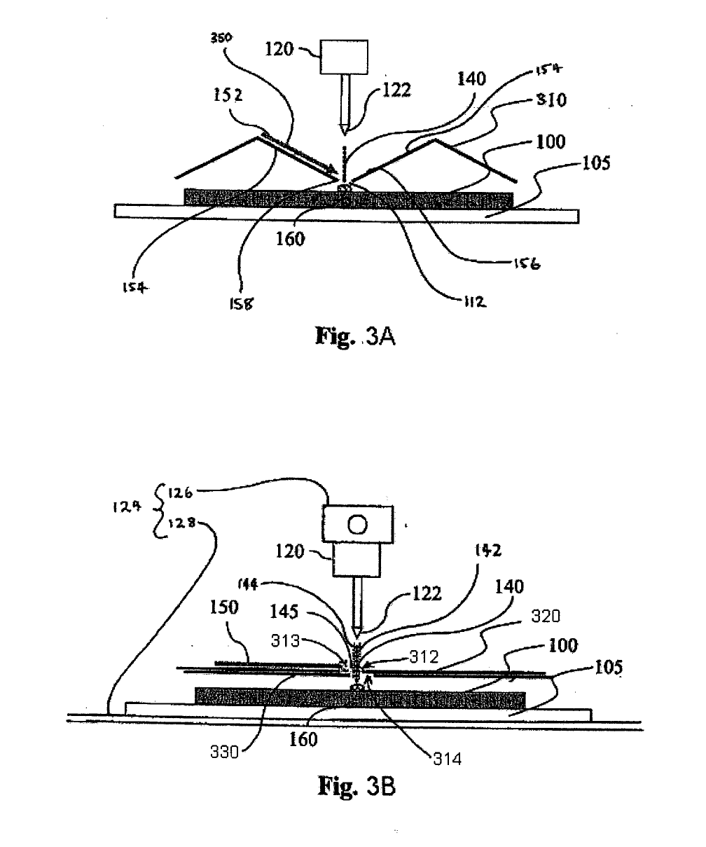

The substrate 100 is held onto the stage platen 105 using a vacuum. If the substrate area is considerably less than the area of the stage platen 105, then the platen area not covered by the substrate 100 can be covered by a thin sheet of material (e.g., thin glass, polycarbonate or aluminium) to enable a sufficient vacuum pressure to be maintained such that the substrate 100 does not move on the stage platen 105 as the stage moves during the deposition process. In the preferred arrangement, the continuous stream deposition device 120 has a single fixed nozzle 122. A transport system is used to achieve patterned deposition by moving the stage platen 105 according to a vector path 190 while the nozzle 122 is continuously discharging a continuous stream 140 to deposit the selected material. In alternative arrangements, the continuous stream deposition device 120 can have an array of nozzles, with the nozzles being either under individual jetting control or a single jetting control. An array of nozzles is advantageous when the deposition pattern is very regular (e.g., a set of parallel lines such as frequently used for front-grid patterns on silicon solar cells). Other alternative arrangements can employ a transport system whereby the nozzle 122, or a set of nozzles, is incorporated into a moveable printhead which can be moved across a fixed stage platen 105. The transport system may be a combination of these two arrangements. For example, FIG. 1C shows a system for depositing material in locations on the substrate 100 which has a transport system 124 including a moveable printhead 126 which can be used to achieve deposition in one direction (raster direction) (in a direction perpendicular to the plane of the sheet on which FIG. 1C is printed), and a belt system 128 for stage motion which can be used to move the sample in a direction perpendicular to the raster motion. This type of combination arrangement is frequently employed by inkjet printing devices. In FIG. 1C, for simplicity, a planar mask 110 is shown. However, contoured masks such as mask 310 shown in FIG. 3 and mask 410 shown in FIG. 4 and discussed in more detail later may also be employed in the system illustrated in FIG. 1C.

The stage platen 105 is preferably heated to a temperature within a range of 45 to 55° C., which might typically be a temperature of 45° C. Higher platen temperatures may also be used, however, the resulting etched regions are typically smaller at higher platen temperatures, and the etching rate is reduced due to the significant loss of solvent by evaporation at the higher temperatures. Furthermore, lower platen temperatures are desirable in order to minimise the risk of the formation of hydrogen fluoride vapour which can form from anhydrous ammonium fluoride at temperatures of about 100° C. or greater.

A deposition mask 110 which contains at least one mask opening 112 is placed above the substrate 100. Preferably, the deposition mask 110 is a thin aluminium sheet having, for example, a thickness of about 0.5 mm which is supported level and parallel to the substrate 100 on the stage platen 105 by thicker aluminium side sheets (e.g., 114 in FIG. 1D) on each side of the mask 110. These side sheets may have a width of approximately 1 mm or greater. If a very large mask is required, the deposition mask 110 can be strengthened by the addition of further strips of aluminium parallel to the direction of the openings. Preferably, the deposition mask 110 is maintained at a distance of 5 mm or less above the substrate 100, and is typically maintained within a range of 2-5 mm above the substrate 100.

The deposition mask 110 can be manually positioned over the substrate 100, with alignment between substrate 100 and deposition mask 110 being achieved by aligning pre-determined reference marks on the two components. For example, the deposition mask 110 can be designed such that the top left hand corner of the mask should align with the top left hand corner of the substrate 100.

Alternatively, the deposition mask 110 can be made from a transparent material such as teflon-coated glass or a rigid plastic such as polycarbonate, polypropylene or polystyrene. In this case, the continuous deposition device 120 can be aligned with a reference (or alignment) mark placed on the substrate 100 which is visible through the transparent material of the deposition mask 110. Transparent deposition masks are also preferred when it is beneficial to observe the deposition process using, for example, a camera which tracks the stage motion.

In a further variation, the deposition mask 110 can be fixed to the stage platen 105. This arrangement is advantageous when the system is designed for a single optimised process, such as the etching of hole arrays for metal contacts to silicon solar cells. With this variation, silicon wafer substrates can be delivered accurately to the correct location under the deposition mask 110 by a belt system, such as frequently used in solar cell fabrication process lines.

Preferably, the deposition mask 110 contains a plurality of openings which are substantially linear openings 112. The linear openings 112 are aligned approximately perpendicular to path followed by the continuous stream 140. With this arrangement, each single linear opening 112 can be used to etch a large number of individual holes in the substrate 100. The width of the linear openings 112 in the deposition mask 110 can be varied to achieve the desired etched hole width. The size of structures produced is likely to be determined by a combination of the width of the opening 112 and the width of the stream of material to be deposited within the continuous stream 140 (discussed in more detail below). For example, the use of linear openings which are 10 μm wide with a continuous stream comprising a stream of the material of 10 μm typically results in etched holes having a width of approximately 10 μm using the substrate 100 of the preferred arrangement. Clearly different substrates will interact differently to the deposited material and may result in difference hole widths. The linear openings 112, if they are required to be very narrow, are preferably patterned in the deposition mask 110 using photolithography. However, other patterned etching techniques can also be used if sufficiently narrow linear openings can be etched.

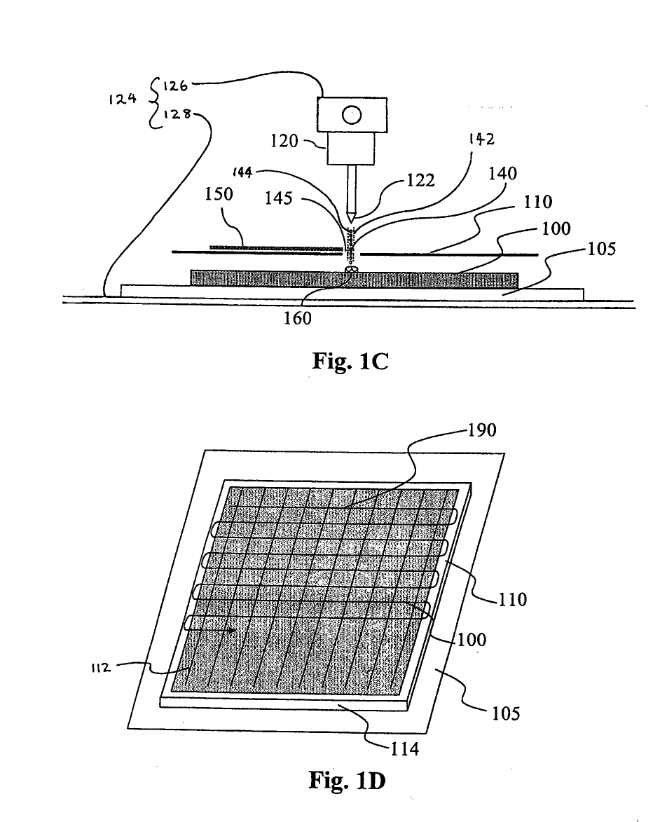

The spacing between the linear openings 112 is selected to be the distance required between the holes in the desired hole array. A range of hole spacings can be achieved using a single deposition mask by simply rotating the mask relative the substrate as described later with reference to FIG. 2.

Once the deposition mask 110 is in place, then a continuous stream deposition device 120 is used to deposit a stream of the required material 140. The stage is moved under process control in a direction 130, in this case, approximately perpendicular to the openings 112 in the deposition mask 110. Preferably, the continuous stream deposition device 120 is an aerosol jet printer which deposits an aerosol of aqueous ammonium fluoride. Other sources of fluoride ion can also be used including but not limited to a tetra alkyl ammonium fluoride, sodium fluoride, and lithium fluoride. Preferably, the aerosol is formed from a solution of 5-15% (w/v) ammonium fluoride in water using an ultrasonic atomiser. The pH of the solution being atomised can be modified to be between 7 and 9, and more preferably about 9, to minimise any etching of the atomiser components.

As is illustrated in FIG. 1C, the continuous stream 140 may comprise other elements, such as sheath gases 142, in addition to the material 144 which is to be deposited on the substrate 100. The sheath gases 142 may be used to constrain the material 144 to be deposited. As a result, the width of the stream of material 144, for example, the aerosol of aqueous ammonium fluoride, within the continuous stream 140 will be less than the total width of continuous stream 140.

The flow rate of the aerosol jet printer can be controlled, with larger flow rates being used to create larger etched holes. The aerosol, together with sheath gases 142 which constrain the spread of the aerosol, is jetted out of a nozzle 122 having a diameter of, for example, 100 μm. Typically, a nozzle 122 having a diameter of 100 μm will produce a continuous stream of 100 μm, and within that continuous stream, the width of the stream of aerosol may be 10 μm. Different nozzle diameters can be used depending on the size of the required features. Aerosol jet printing can also be used to deposit aerosols of metals and thus can be used for point-wise additive patterning of a substrate.

As the stage platen 105 moves the substrate 100 and deposition mask 110 relative to the continuous stream deposition device 120, material deposited over the linear openings, or grooves, 112 in the mask contacts the substrate 100 and forms a deposit 160. If the direction of the continuous stream deposition device 120 relative to the deposition mask 110 is approximately 90 degrees, then the shape of the region in which the deposited material contacts the substrate is approximately rectangular. However, depending on factors such as the width of the opening 112, the width of stream of material, the amount of material deposited on the substrate 100 and the properties of the deposited material, for example, surface tension, an approximately circular pattern of deposition may result.

Material that is deposited on the deposition mask surface between the openings 112 forms a trace of material 150 on the mask 110. Depending on the nature of the deposited fluid, this trace 150 can dry on the surface to leave a trace of dried residue. This dried material needs to be removed periodically by washing. In the preferred arrangement, this cleaning step can be performed at substantially the same time as when the polymer and etch residue are removed from the substrate 100.

In the preferred arrangement, the deposit 160 almost immediately dissolves in the polymer layer 106 of the substrate 100. The fluoride ions abstract protons from the polyacrylic acid and form an active hydrofluoric acid etchant which then etches the underlying silicon dioxide layer 104. If the shape of the region where the continuous stream 140 contacts the substrate 100 is approximately circular, then circular holes are etched in the silicon dioxide layer 104. This etching method can also be used to etch silicon nitride dielectric layers. The etching product silicon hexafluorosilicate remains soluble in the aqueous etching environment around the created hole. Because six fluoride ions are required to remove each silicon atom from the silicon dioxide crystal matrix, typically a number of passes of the etching pattern must be made. For substrates which contain component materials that etch more slowly than silicon dioxide (e.g., silicon nitride), time delays can be introduced between the subsequent deposition passes, or layers.

Preferably, an etching pattern is represented as a vector path. The stage platen 105 simply follows the required vector path 190, as shown in FIG. 1D, for the required number of layers. There is no need to stop the flow at the end of a line as turns can be made over the deposition mask 110. For example, typically 10-20 layers are required to etch holes in a 200 nm thick oxide layer using the deposition mask 110 shown in FIG. 1.

Once etching is completed both the substrate 100 and deposition mask 110 are washed in water to remove the polymer and etching residue from the substrate 100 and the dried material from the deposition mask 110. The array of holes (or openings) 180 in the substrate 100, as shown in FIG. 1E, can then be used to form metal contacts to the silicon solar cell. The metal contacting process involves first performing a boron diffusion (if the original wafer was p-type) to create a heavily doped p+ region at the base of the holes which can then form ohmic contact to deposited metal. Then a metal such as aluminium is evaporated or screen printed over the entire rear surface to form the rear metal contacts. Clearly, numerous variations exist for rear-side metal contacting in silicon solar cell fabrication, and the described method of forming an array of etched holes in a dielectric layer can be used with any of these processes. For example, silicon nitride can also be used as a rear passivating layer and the preferred arrangement of the current invention can also be used to etch hole regions in these layers.

FIG. 2 depicts a variation of the preferred arrangement whereby the deposition mask 110 can be rotated over the substrate 100. This rotation of the mask over the substrate 100 can be used to obtain different spacing between the adjacent holes in a row. The relationship between hole spacing, l, and the spacing between the linear mask openings 112, x, is given by, l=x/sin a, where a is the angle between the linear opening 112 on the grid and the stage motion (i.e., deposition) direction. The spacing between rows is achieved by moving the stage platen 105 according to the vector path.

The rotation of the deposition mask 110 can be achieved by manual placement of the mask over the substrate 100 on the stage platen 105. However, it is preferable to use a mechanically controlled deposition mask holder which can be rotated more accurately to precisely locate the mask. A vernier scale on the perimeter of the mask holder can be used to specify the required rotation angle.

Specific shaping of the points of the pattern can also make use of the increased effective width of the openings 112 that occurs on rotation. As the angle a becomes smaller, then the shape of the patterned region (which is etched in the preferred arrangement) becomes less rectangular, or circular, as the case may be, and more elongated and parallelogram-shaped etched regions can result.

FIG. 3A shows a further variation of the preferred arrangement where sloping walls 154 in a deposition mask 310 are used to direct fluid 350 that is deposited on the mask area 152 into the nearest mask opening 112. The sloping walls 154 form a valley 156 with the lowest point 158 of the valley 156 corresponding to the opening 112. For the etching reaction of the preferred arrangement, this represents a way of increasing the extent of etching without the requirement to deposit more layers or increase the aerosol flow rate. The fluid 350 that is directed into the mask opening 112 in this manner, enters the opening 112 at a short interval after the continuous stream 140 has passed the opening 112. This is advantageous in that no extra spreading occurs on the substrate 100 as the fluid deposited directly by the continuous stream deposition device 120 has already been absorbed and commenced reacting.

The angle of the sloping 154 walls of the deposition mask 310 depends on the nature of the material deposited. The sloping walls 154 are only advantageous if the deposited material remains sufficiently liquid for a period after being deposited. The angle of the sloping walls 154 can be adjusted to account for the fluidity of the material deposited on the mask 310 and the extent to which redirection of that fluid is advantageous for the specific application. In yet a further variation, the sloping walls 154 do not have to extend over the entire region between openings 112 in the deposition mask 310, thus restricting the amount of fluid that can be re-directed into the nearest mask opening 112.

As seen in FIG. 3B, a further variation to this general approach of using sloping walls to direct fluid to the nearest mask opening can be achieved by aligning two or more separate planar masks 320, 330, having openings 313, 314 of the same periodicity, such that that the effective opening width 312 is significantly less than that of the openings 313, 314 of individual deposition masks 320, 330. This arrangement is advantageous because it means that the deposition masks 320, 330 can be fabricated using wider (i.e., larger) openings 313, 314 using standard machining processes. Preferably the individual planar masks 320, 330 are clamped together such that the effective mask openings 312 can be adjusted as required. So for example, two individual masks with openings in the order of 100 μm can be clamped together in an aligned fashion to achieve openings of dimensions approaching 20 μm. The overlapping arrangement effectively creates a stepped edge on at least one side of the opening 312 which can assist flow of the deposited fluid 150 into the groove to effect etching of the underlying dielectric 100.

FIG. 4 shows a variation in which a deposition mask 410 is shaped to enhance flow of fluid 450 which is deposited on the mask 410 away from the mask openings 112. Fluid is collected in the valley regions 411 of the deposition mask 410 and the valley regions 411 form channels 418 along which the fluid can be channelled into a fluid reservoir 420 through conduit 422 for waste or recycling. In this variation, the sloping walls 454 of the valley regions 411 rise to a ridge 414 having a peak 416 at a location corresponding to the opening 112. This variation is advantageous when the stream is very fluid and enables capture and recycling of the fluid which is deposited on the mask 410 and not required for the process at the mask openings 112. To facilitate the flow of the fluid along the channels 418, the valley regions 411 may be shallower at one end of the mask 410 and deeper at the other end of the mask 410 to form a gradient down which the fluid flows for collection. In another arrangement, the valleys regions 411 are shallower in the middle of the mask 410 and are progressively deeper toward each end of the mask 410 with the fluid being collected at each end of the mask 410. Finally a combination of the mask structures shown in FIG. 3 and FIG. 4 can be used to direct a fraction of the fluid deposited on the mask into the mask openings 112 and then channel the remaining fluid to a waste or recycling reservoir 420.

In a further variation, the deposition mask 110 can be deposited or printed using a printing device such as a screen printer, drop-on-demand inkjet printer, continuous inkjet printer, electrohydrodynamic printer, or aerosol jet printer. Preferably, the material used to form the printed deposition mask is a resin, such as a novolac resin from the group of resins commonly used as a photolithography mask. Though other polymers (e.g., Teflon), that are resistant to the deposition material can also be used.

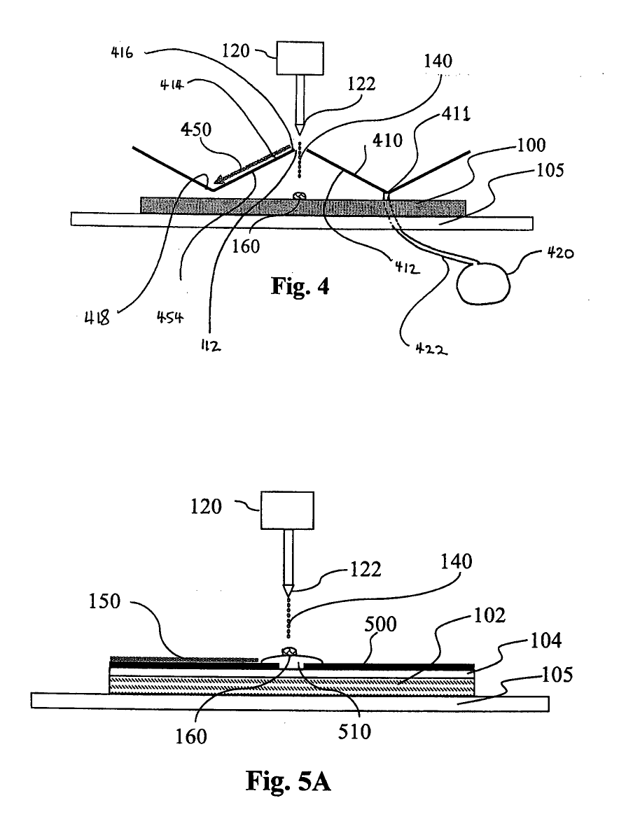

In the simplest arrangement, a printed deposition mask 110 can be formed over the substrate 100 as shown in FIG. 1C and the etched hole array can be produced substantially as described with reference to the FIGS. 1A to 1D. FIG. 5A depicts an alternative use of a printed deposition mask. In this case, the printed deposition mask 500 is printed directly over the dielectric layer 104 to be patterned. The acidic polymer can then be deposited in a separate printing process to lie over the openings in the printed deposition mask 500. The polymer deposits 510 are then dried as described in the preferred arrangement. The continuous stream 140 containing fluoride ions is then deposited by the continuous stream deposition device 120 as described for the preferred arrangement.

In the alternative arrangement depicted in FIG. 5B, the acid source for the etching reaction is also deposited by the continuous stream deposition device 120. One way of achieving co-deposition is to use a continuous deposition device 120 having the ability to jet from two sets of nozzles 520 and 522 as shown in FIG. 5B. Alternatively, a single nozzle (or set of nozzles) can be used and the two component materials (e.g., the acid and fluoride components) can be jetted as a mixture through the same nozzle. The aerosol jet printer which is used as the continuous stream deposition device 120 in the preferred arrangement can be configured to jet two separate aerosol streams, each with their own individual flow rates, through a single nozzle. Because the particles in the aerosol are very small they have a high surface tension which makes it unlikely for particles to merge, especially when the diameter of the particles of the two aerosols is similar. When the arrangement depicted in FIG. 5B is applied to the etching system described for the preferred arrangement, a range of different acid sources can be used. For example, lower molecular weight organic acids such as acetic acid and acrylic acid can be used. However, polymeric acids such as polyacrylic acid have the advantage of being more viscous and spread less on contacting the dielectric surface.

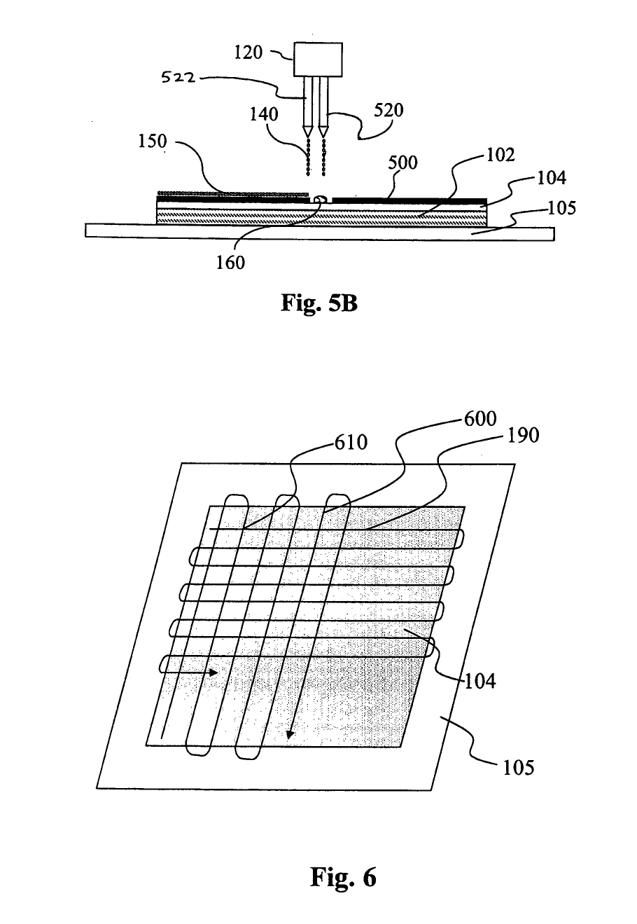

FIG. 6 depicts a further arrangement in which the fluoride source and acid source are both deposited by a continuous stream deposition device 120 such that the deposition paths 190 and 600, respectively, intersect each other at the positions (e.g., 610) where the etching of holes is required. The fluoride and acid sources can be deposited using a two nozzle arrangement of the continuous stream deposition device 120 as shown in FIG. 5B. The continuous stream deposition device 120 can be programmed to deliver the acid and fluoride source in alternative passes, or layers, thus ensuring that excess build-up or drying of the materials does not occur on the dielectric layer 104 of the substrate 100. If an excess of one of the materials is deposited the trace of deposited material can spread resulting in larger etched features. Preferably, the acid source is delivered as a solution or aerosol of an acidic polymer solution, such as polyacrylic acid, in order to reduce the amount of spreading that occurs as the acid source contacts the dielectric layer 104 of the substrate 100, though clearly other acid sources could also be used. The final size of the etched holes depends on the overlap area where the two deposition paths 190 and 600 intersect. Preferably, the two deposition paths intersect approximately perpendicular to each other in order to achieve the smallest possible area of etching.

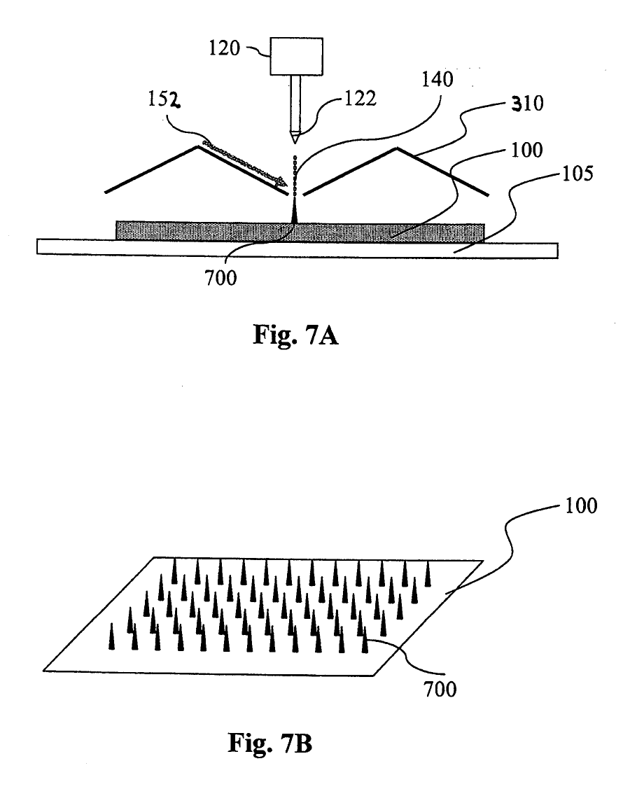

The processes described generally above are not limited to the etching of hole arrays as described above in the preferred arrangement. It can also be used to form arrays of small point structures 700 on a surface as shown in FIG. 7A and FIG. 7B where a deposition mask 310 is used to constrain the delivery of the material to discrete locations on the substrate 100. For example, a metal-containing solution or aerosol, deposited by the continuous stream deposition device 120, can be used to form very small discrete pillar structures 700. Alternatively, the arrangements depicted in FIG. 6 can be used to deliver a moulding material and a curing agent. It is preferable for this arrangement that the moulding material and curing agent are delivered in alternate passes to ensure a uniform moulding process. Arrays of small point structures can be used for light capturing applications and more generally in photonic devices.

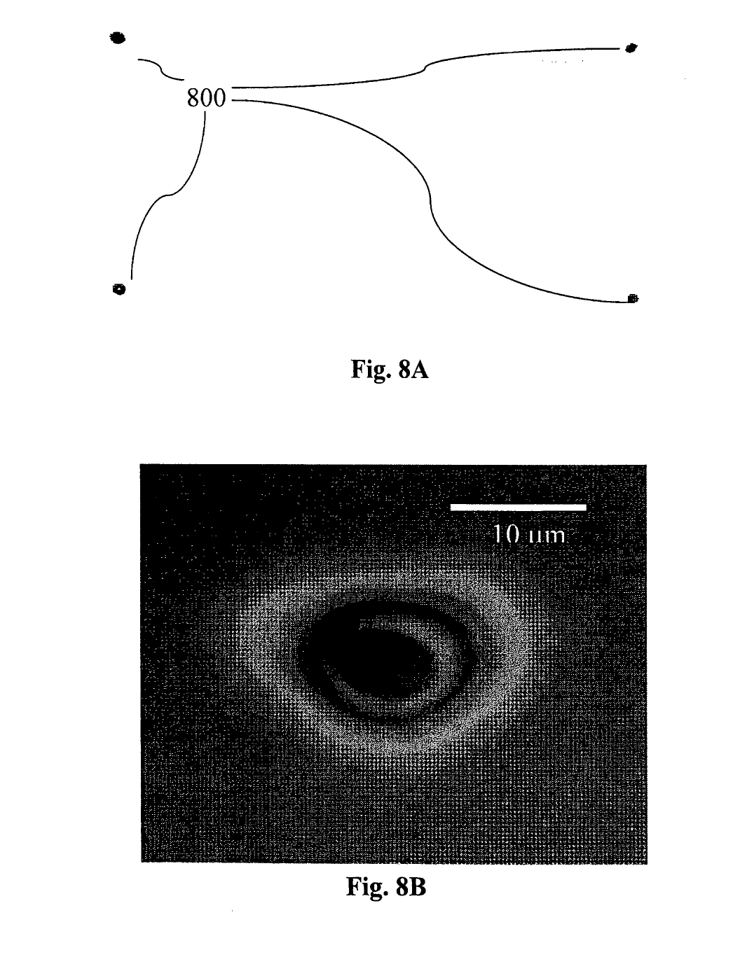

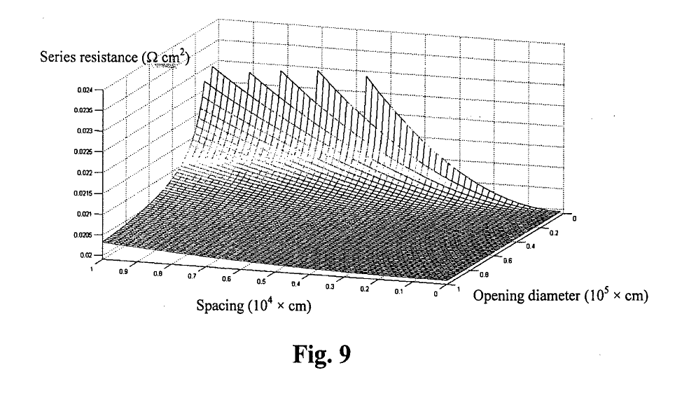

FIG. 8A shows an image of etched holes which were formed in a silicon dioxide dielectric layer. The average diameter of the formed holes is ˜10 μm at the perimeter at the surface of the dielectric, as shown by the more highly magnified image shown in FIG. 8B. Because of the shaped side edges of the holes, the actual diameter at the bottom of the hole is much smaller. The ability to create such small openings in a dielectric layer has the potential to reduce metal-silicon recombination losses in solar cells. Furthermore it has been shown for solar cells that rely on point rear contacts, series resistive losses can be minimised by having very small openings located very close to each other as shown by FIG. 9.

Close spacings between adjacent holes can be achieved either by reducing the spacing between openings in deposition masks 110, or in the case of the variation described with respect to FIG. 6, by depositing polymer in more closely-spaced lines.

1-67. (canceled)

68. A method of processing a surface at a discrete location on a substrate using a continuous stream deposition device, the method comprising:
depositing a first component according to a first deposition path;
depositing a second component according to a second deposition path, the second deposition path intersecting the first deposition path at the discrete location; and
modifying the substrate only at the discrete location by the action of the first component and the second component together.

69. The method as claimed in claim 68, wherein the surface is additively modified.

70. The method as claimed in claim 68 wherein the first component is reactive with the second component.

71. The method of claim 68 wherein the first component and the second component react with each other at the surface of the substrate to become reactive with respect to a component of the substrate to modify the substrate at the discrete location.

72. The method as claimed in claim 68, wherein the substrate is modified by etching of a component of the substrate.

73. The method of claim 68, wherein the second deposition path intersects the first deposition path at a predetermined angle.

74. The method as claimed in claim 68 wherein the continuous stream deposition device is one of a continuous flow inkjet device, an electrohydrodynamic printing device, and an aerosol jet printing device.

75. The method of claim 74, wherein the continuous stream is an aerosol stream.

76. The method of claim 75, further including controlling a flow rate of the aerosol stream and constraining the aerosol stream with a sheath gas.

77. The method as claimed in claim 68 wherein the first component contains one of a source of fluoride ions and acidic polymer and the second component contains the other of the source of fluoride ions and the acidic polymer.

78. The method of claim 77, wherein the source of fluoride ions is one or more of: ammonium fluoride, a tetra alkyl ammonium fluoride, sodium fluoride, and lithium fluoride.

79. The method of claim 77 wherein the acidic polymer is water-soluble.

80. The method of claim 72, wherein the component of the substrate which is etched is one of a compound selected from silicon dioxide, silicon nitride and silicon carbide; a transparent conducting oxide; a glass; an organic resin; a pattern mask material; a metal selected from aluminium, copper, silver, gold, tin, lead and alloys thereof; a semiconductor material selected from silicon, germanium, gallium-arsenide and indium phosphide; and a semiconductor alloy selected from silicon-germanium, aluminium-gallium-arsenid, indium-selenide, galium-selenide, cadmium-telluride and copper indium gallium selenide (CIGS).

81. The method of claim 72, wherein the substrate is a silicon solar cell device precursor having a dielectric layer and the etching results in an array of openings in the dielectric layer.

82. The method of claim 81, wherein the openings are used to form metal contacts to the silicon solar cell device.
